(19) United States
(12) Patent Application Publication
(10) Pub. No.: US 2011/0300696 A1
(43) Pub. Date: Dec. 8, 2011

(54) METHOD FOR DAMAGE-FREE JUNCTION FORMATION

(75) Inventors: Christopher R. HATEM, Salisbury, MA (US); Ludovic GODET, Boston, MA (US)

(73) Assignee: VARIAN SEMICONDUCTOR EQUIPMENT ASSOCIATES, INC., Gloucester, MA (US)

(21) Appl. No.: 12/792,190

(22) Filed: Jun. 2, 2010

(51) Int. Cl. H01L 21/26

(52) U.S. Cl. 438/513; 257/E21.328

(57) ABSTRACT

Embodiments of this doping method may be used to improve junction formation. An implant species, such as helium or another noble gas, is implanted into a workpiece to a first depth. A dopant is deposited on a surface of the workpiece. During an anneal, the dopant diffuses to the first depth. The noble gas ions may at least partially amorphize the workpiece during the implant. The workpiece may be planar or non-planar. The implant and deposition may occur in a system without breaking vacuum.

### FIELD

This invention relates to junction formation and, more particularly, to junction formation using ion implantation prior to deposition.

### BACKGROUND

Ion implantation is a standard technique for introducing conductivity-altering impurities into a workpiece. A desired impurity material is ionized in an ion source, the ions are accelerated to form an ion beam of prescribed energy, and the ion beam is directed at the surface of the workpiece. The energetic ions in the beam penetrate into the bulk of the workpiece material and are embedded into the crystalline lattice of the workpiece material to form a region of desired conductivity.

In a silicon workpiece, one silicon atom is usually tetrahedrally bonded to four neighboring silicon atoms to form a well-ordered lattice across the workpiece. This may be referred to as a diamond cubic crystal structure. In contrast, this order does not exist in amorphous silicon. Instead, the silicon atoms in amorphous silicon form a random network and the silicon atoms may not be tetrahedrally bonded to four other silicon atoms. In fact, some silicon atoms may have dangling bonds.

Amorphizing implants, such as a pre-amorphizing implant (PAI), are used to amorphize the crystal lattice of a workpiece. Prior to the amorphizing implant, the workpiece usually has a crystal lattice with a long-range order, such as the tetrahedrally-bonded crystal structure. This ordered crystal lattice may allow implanted ions to move through the crystal lattice or channel substantially between the atoms of the crystal lattice. By amorphizing the workpiece, channeling of dopants during later implantation may be prevented or reduced because the workpiece will lack the long-range order. Thus, the dopant implant profile may be shallower because ions will not channel deeper into the workpiece.

Forming a damage-free, highly-activated, an abrupt electrical junction becomes more challenging as semiconductor devices are scaled down. This is especially true for extremely thin silicon-on-insulator (ETSOI) or FinFet devices. While deposition systems and diffusion furnaces have been used, it is difficult to control diffusion of dopants into the device to a precise depth. Thus, there is a need in the art for an improved method of precise implantation and, more particularly, improved junction formation.

### SUMMARY

According to a first aspect of the invention, a doping method is provided. The method comprises implanting a noble gas into a workpiece to a first depth. A dopant is deposited on a surface of the workpiece. The workpiece is annealed such that the dopant diffuses to the first depth.

According to a second aspect of the invention, a doping method is provided. The method comprises implanting a noble gas to a first depth into a plurality of non-planar surfaces of a workpiece. A dopant is deposited on the plurality of non-planar surfaces. The workpiece is annealed such that the dopant diffuses to the first depth of the plurality of non-planar surfaces.

According to a third aspect of the invention, a doping method is provided. The method comprises placing a workpiece into a process chamber. A vacuum is formed in the process chamber. A noble gas plasma is formed in the process chamber. Noble gas ions are implanted into the workpiece to a first depth. The process chamber is filled with a dopant species and the dopant species is deposited on the workpiece. The workpiece is removed from the process chamber and the vacuum is broken. The workpiece is annealed such that the dopant diffuses to the first depth of the workpiece.

### BRIEF DESCRIPTION OF THE DRAWINGS

For a better understanding of the present disclosure, reference is made to the accompanying drawings, which are incorporated herein by reference and in which:

FIG. 1 is a block diagram of a plasma doping system;

FIGS. 2-5 are a cross-sectional side diagrams illustrating a first embodiment of doping a workpiece;

FIGS. 6-9 are a cross-sectional side diagrams illustrating a second embodiment of doping a workpiece; and

FIGS. 10-13 are a block diagrams illustrating a third embodiment of doping a workpiece.

### DETAILED DESCRIPTION

The embodiments of this process are described herein in connection with a plasma doping ion implanter. However, these embodiments can be used with other systems and processes involved in semiconductor manufacturing or other systems that use implantation or deposition. For example, in an alternate embodiment, a beamline ion implanter is used with a deposition system. Thus, the invention is not limited to the specific embodiments described below.

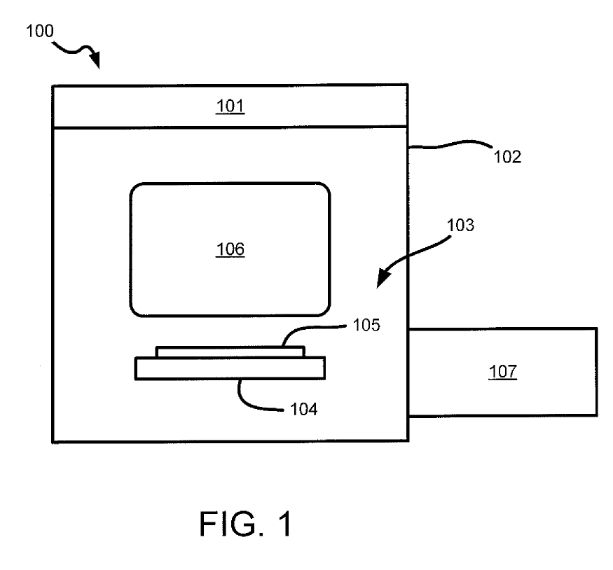

Turning to FIG. 1, the plasma doping system 100 includes a process chamber 102 defining an enclosed volume 103. A load lock 107 is connected to the process chamber 102. The load lock 107 may pump down to vacuum or vent to atmosphere when a workpiece 105 is inside. The process chamber 102 or workpiece 105 may be cooled or heated by a temperature regulation system, such as within the load lock 107. A platen 104 may be positioned in the process chamber 102 to support a workpiece 105. The platen 104 also may be cooled or heated by a temperature regulation system. Thus, the plasma doping system 100 may incorporate hot or cold implantation of ions in some embodiments. In one instance, the workpiece 105 may be a semiconductor wafer having a disk shape, such as, in one embodiment, a 300 mm diameter silicon wafer. However, the workpiece 105 is not limited to a silicon wafer. The workpiece 105 may be clamped to a flat surface of the platen 104 by electrostatic or mechanical forces. In one embodiment, the platen 104 may include conductive pins for making connection to the workpiece 105.

The plasma doping system 100 further includes a source 101 configured to generate a plasma 106 from an implant gas within the process chamber 102. The source 101 may be an RF source or other sources known to those skilled in the art. The platen 104 may be biased. This bias may be provided by a DC or RF power supply. The plasma doping system 100 may further include a shield ring, a Faraday sensor, or other components. In some embodiments, the plasma doping system 100 is part of a cluster tool, or operatively-linked process chambers 102 within a single plasma doping system 100. Thus, numerous process chambers 102 may be linked in vacuum. Some process chambers 102 may implant while others deposit in these embodiments.

During operation, the source 101 is configured to generate the plasma 106 within the process chamber 102. In one embodiment, the source 101 is an RF source that resonates RF currents in at least one RF antenna to produce an oscillating magnetic field. The oscillating magnetic field induces RF currents in the process chamber 102. The RF currents in the process chamber 102 excite and ionize the implant gas to generate the plasma 106. The bias provided to the platen 104 and, hence, the workpiece 105 will accelerate ions from the plasma 106 toward the workpiece 105 during bias pulse on periods. The frequency of the pulsed platen signal and/or the duty cycle of the pulses may be selected to provide a desired dose rate. The amplitude of the pulsed platen signal may be selected to provide a desired energy. With all other parameters being equal, a greater energy will result in a greater implanted depth.

As stated above, silicon is typically a crystalline structure, where each silicon atom is tetrahedrally bonded to four neighboring silicon atoms. Ion implantation may be used to form an amorphous structure in the silicon. In one instance, a partially or fully amorphized crystal structure may be formed using a PAI. By bombarding this crystalline structure of the workpiece with atoms or ions, such as helium, the crystalline structure of the silicon may be altered. An amorphous crystal structure lacks a long-range order and includes some atoms with dangling bonds. Since this crystal lattice lacks a long-range order, the channels within the crystal lattice do not exist. Thus, ions are unable to channel between the crystal lattice of the workpiece.

While PAI eliminates the channeling issue, it causes other problems. The implantation of ions, specifically heavier species such as germanium and silicon, causes residual damage at end of range (EOR). The end of range is the lowest depth within the workpiece where implanted ions reach. These EOR defects cause subsequent leakage in a CMOS transistor. Ultra shallow junctions also require annealing techniques capable of millisecond (MS) thermal budgets near the target temperature. Two drawbacks of the MS anneal are the inability to completely remove the implant damage from heavier species, specifically the EOR defects described above, and the lack of lateral diffusion of the dopant, which causes overlap capacitance issues within the device.

A helium implant may not only prevent channeling of ions, but also may enable a millisecond (MS) anneal. A helium implant has the ability to partially or fully amorphize a workpiece so that channeling of ions is prevented. In addition, it has been found that a helium implants result in no or low residual damage after annealing. A helium PAI also will fully repair with a solid phase epitaxy (SPE) anneal or MS anneal. Furthermore, because there is no residual damage, a helium PAI also will not cause substantial leakage, unlike a germanium PAI.

Additionally, during the anneal process after a helium implant, some implanted dopant ions, such as boron, arsenic, phosphorus, or others, will transport to the original amorphous-crystalline interface that was created by the helium implant. Tests have shown that these implanted ions do not diffuse past the original amorphous-crystalline interface, and instead stop at this interface. This transport phenomenon gives helium the ability to tailor junction depth (Xⱼ) and/or lateral diffusion (Yⱼ). A helium PAI may, thus, enable an MS anneal by overcoming issues associated with lateral diffusion. While helium is specifically named herein, other species, such as noble gases, may have the same effect.

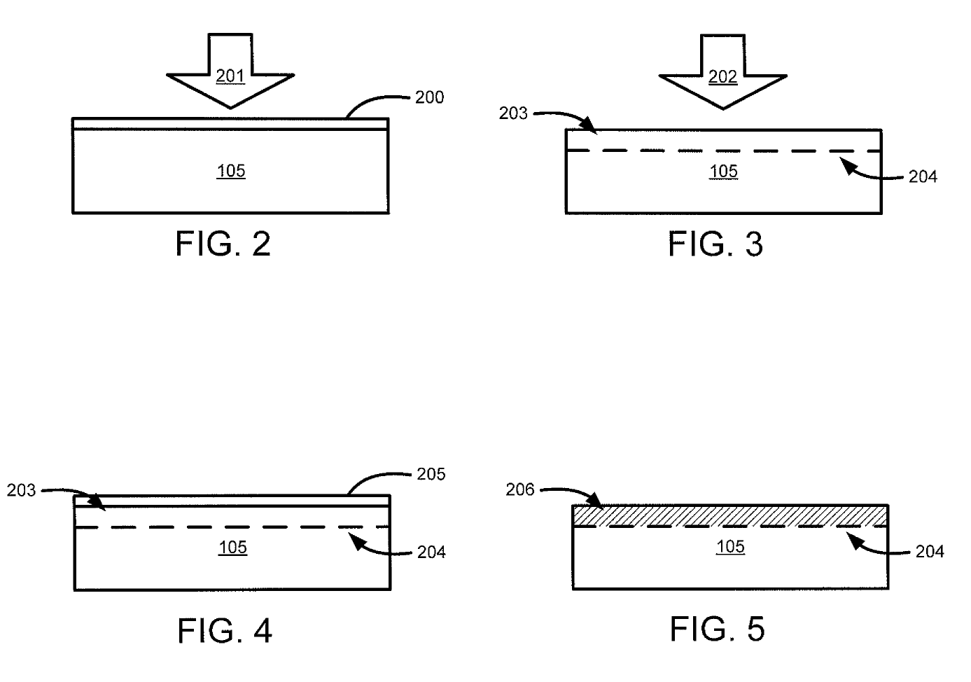

FIGS. 2-5 are a cross-sectional side diagrams illustrating a first embodiment of doping a workpiece. In FIG. 2, the workpiece 105 may have an oxide coating 200 on the surface. A sputtering species 201, such as argon or some other noble gas, is used to remove the oxide layer 200 from the workpiece 105. Of course, the oxide layer 200 also may not be removed prior to implant or may not be present. In an alternate embodiment, a plasma etch or wet strip step is used to remove the oxide layer 200.

In FIG. 3, a PAI is performed using an implant species 202. The implant species 202 may be helium, another noble gas, or another PAI species known to those skilled in the art. The implant species 202 is implanted to a first depth 204 (represented by the dotted line in FIG. 3) within the workpiece 105. This forms an amorphized region 203 between the first depth 204 and a surface of the workpiece 105. In one particular instance, the dose or energy of the PAI is configured such that the PAI does not fully amorphize the workpiece 105. Rather, the PAI only partially amorphizes the workpiece 105. Partial amorphization may result in pockets of amorphization within a crystalline structure. Thus, a region may be amorphized but a neighboring region may still be crystalline and not all bonds within the crystal lattice of the workpiece 105 are broken.

A dopant 205 is deposited on the workpiece 105 in FIG. 4. This dopant may be, for example, an atomic or molecular species containing boron, phosphorus, arsenic, germanium, carbon, or other dopants known to those skilled in the art. In FIG. 5, the workpiece 105 is annealed and the dopant 205 diffuses to the first depth 204. This forms a doped region 206 (illustrated in FIG. 5 by shading) in the same region as the amorphized region 203. In one particular embodiment a millisecond (MS) anneal is performed.

The PAI is used to control diffusion of the dopant 205. The dopant 205 will only diffuse to the amorphous-crystalline interface at the first depth 204. Use of helium or other noble gases for the PAI also reduces implant damage and enables use of an MS anneal. Helium or other noble gases also enhances activation and enables for Xⱼ and Yⱼ control during annealing.

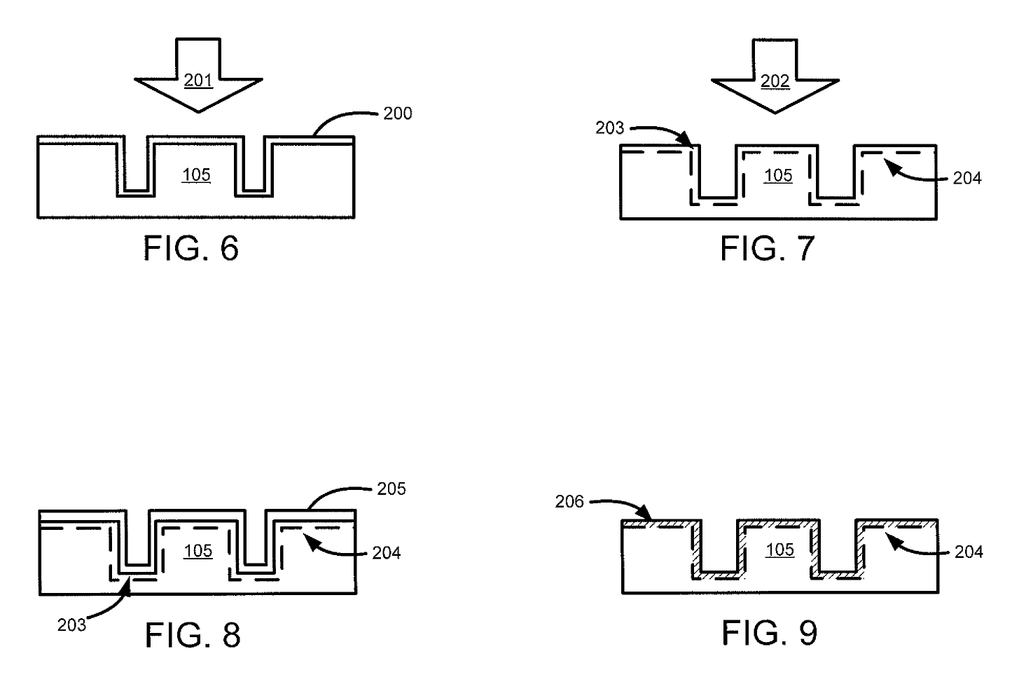

FIGS. 6-9 are a cross-sectional side diagrams illustrating a second embodiment of doping a workpiece. Whereas the workpiece 105 in FIG. 2 was planar, the workpiece 105 in FIG. 6 is non-planar. The workpiece 105 may be, for example, a FinFet, a series of trenches, or some three-dimensional device. Other three-dimensional or non-planar structures than that illustrated in FIGS. 6-9 are possible.

The workpiece 105 in FIG. 6 may have an oxide coating 200 on the surface. A sputtering species 201, such as argon or some other noble gas, is used to remove the oxide layer 200 from the workpiece 105. Of course, the oxide layer 200 also may not be removed prior to implant or may not be present. In an alternate embodiment, a plasma etch or wet strip step is used to remove the oxide layer 200.

In FIG. 7, a PAI is performed using an implant species 202. The implant species 202 may be helium, another noble gas, or another PAI species known to those skilled in the art. The implant species 202 is implanted to a first depth 204 (represented by the dotted line in FIG. 7) within the workpiece 105. This forms an amorphized region 203 between the first depth 204 and a surface of the workpiece 105. As illustrated in FIG. 7, the first depth 204 follows the profile of the workpiece 105. The first depth 204 may be at a uniform depth regardless of this workpiece 105 profile. To make the uniform depth, the angular distribution of the implant species 202 may be controlled. Second, the amorphized region 203 may saturate over time such that any uneven regions will become more even or uniform. Third, the implant that forms the amorphized region 203 may continue until the uniform depth is achieved. Once a section of the crystal structure of the workpiece 105 is amorphized, continuing to amorphize may not affect later results. In one particular instance, the dose or energy of the PAI is configured such that the PAI does not fully amorphize the workpiece 105. Rather, the PAI only partially amorphizes the workpiece 105.

A dopant 205 is deposited on the workpiece 105 in FIG. 8. This dopant may be, for example, an atomic or molecular species containing boron, phosphorus, arsenic, germanium, carbon, or other dopants known to those skilled in the art. The dopant 205 is deposited uniformly regardless of the workpiece 105 profile. A low density plasma or plasma sheath engineering may be used to deposit on the different surfaces of the workpiece 105 evenly. Plasma sheath engineering uses an insulating or biased plate with apertures to direct or focus the ions, atoms, or molecules. This plate modifies an electric field within the plasma sheath to control a shape of a boundary between the plasma and the plasma sheath.

In FIG. 9, the workpiece 105 is annealed and the dopant 205 diffuses to the first depth 204. This forms a doped region 206 (illustrated in FIG. 9 by shading) in the same region as the amorphized region 203. In one particular embodiment a millisecond (MS) anneal is performed.

The embodiments of FIGS. 6-9 enable uniform doping on a non-planar surface. The PAI using the implant species 202 may be used to define the junction depth. The subsequent anneal will activate and drive in the dopant 205.

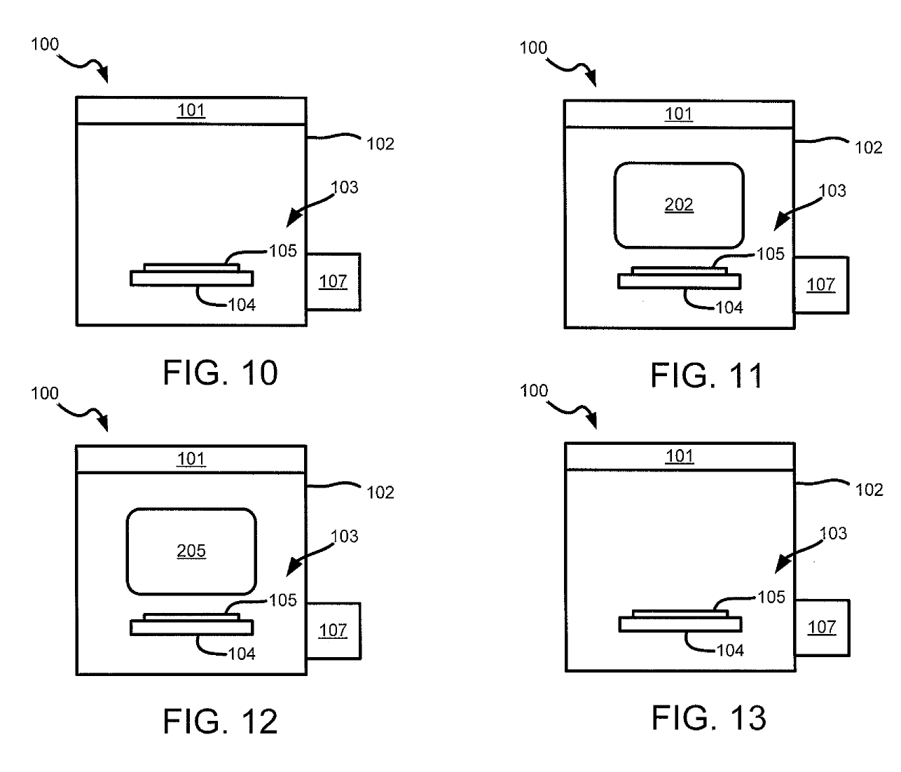

FIGS. 10-13 are a block diagrams illustrating a third embodiment of doping a workpiece. In the embodiments of FIGS. 10-13, the workpiece 105, which may be planar or non-planar, may be processed without breaking vacuum. The workpiece 105 may remain in the process chamber 102 or load lock 107 without breaking vacuum in one example. In one particular embodiment, the workpiece 105 is moved to the load lock 107 when the species in the process chamber 102 is changed.

In FIG. 10 the workpiece 105 is placed in the process chamber 102. The workpiece 105 may be loaded onto the platen 104 using a robot handling system. A vacuum may be formed before or after the workpiece 105 is placed in the process chamber 102.

A plasma of an implant species 202, such as helium or another noble gas, is formed in FIG. 11. In one instance, the workpiece 105 and platen 104 are biased and the implant species 202 is implanted into the workpiece 105 to a particular depth. A dopant species, such as the dopant 205, fills the process chamber 102 in FIG. 12. The dopant 205 may be phosphorus, arsenic, germanium, carbon, or boron, for example. The workpiece 105 may be removed from the process chamber 102 to the load lock 107 when the implant species 202 is switched to the dopant 205. The dopant 205 is deposited on the workpiece 105. The workpiece 105 or platen 104 may not be biased during this deposition.

In FIG. 13, the dopant 205 is removed. The workpiece 105 is removed from the process chamber 102 to the load lock 107. The vacuum is then broken and the workpiece 105 may be removed out of the plasma doping system 100. In another instance, the workpiece 105 may be removed under vacuum to the load lock 107 while the dopant 205 is present. Subsequently, the workpiece 105 may be annealed such that the dopant 205 that is deposited diffuses to the particular depth in the workpiece 105. For example, an MS anneal may be used. Multiple process chambers 102 may be used without breaking vacuum for the steps illustrated in FIGS. 10-13 in an alternate embodiment.

In an alternate embodiment, the plasma doping system 100 may be used to remove any oxide coating from the workpiece 105. The plasma doping system 100 may form a plasma of, for example, argon, which is used to sputter the workpiece 105. This also may occur without breaking vacuum around the workpiece 105. In one instance, the workpiece 105 may be moved to the load lock 107 after the sputtering but prior to the implant species 202 filling the process chamber 102. In another instance the workpiece 105 remains on the platen 104 after sputtering while the implant species 202 fills the process chamber.

By not breaking vacuum during processing, oxide layer growth on the workpiece 105 is prevented or reduced. A sputtering step to remove the oxide layer on the surface of the workpiece 105 may be prevented because oxide growth is minimized if the workpiece 105 is in a vacuum environment. In another instance, an initial oxide layer is sputtered off the workpiece 105 and the vacuum in the plasma doping system 100 prevents subsequent oxide growth. Thus, use of multiple sputtering steps can be avoided.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A doping method comprising:
implanting a noble gas into a workpiece to a first depth;
depositing a dopant on a surface of said workpiece; and
annealing said workpiece wherein said dopant diffuses to said first depth.

2. The doping method of claim 1, wherein said implanting amorphizes a crystal lattice of said workpiece.

3. The doping method of claim 1, wherein said workpiece has an oxide coating on said surface and further comprising removing said oxide coating from said surface prior to said implanting.

4. The doping method of claim 3, wherein said removing comprises sputtering with argon.

5. The doping method of claim 1, wherein said dopant is selected from the group consisting of boron, phosphorus, arsenic, germanium, and carbon.

6. The doping method of claim 1, wherein said annealing comprising a millisecond anneal.

7. A doping method comprising:
implanting a noble gas to a first depth into a plurality of non-planar surfaces of a workpiece;
depositing a dopant on said plurality of non-planar surfaces; and
annealing said workpiece wherein said dopant diffuses to said first depth of said plurality of non-planar surfaces.

8. The doping method of claim 7, wherein said implanting amorphizes a crystal lattice of said workpiece.

9. The doping method of claim 7, wherein said workpiece has an oxide coating on said plurality of non-planar surfaces and further comprising removing said oxide coating from said plurality of non-planar surfaces prior to said implanting.

10. The doping method of claim 9, wherein said removing comprises sputtering with argon.

11. The doping method of claim 7, wherein said dopant is selected from the group consisting of boron, phosphorus, arsenic, germanium, and carbon.

12. The doping method of claim 7, wherein said annealing comprising a millisecond anneal.

13. A doping method comprising:
placing a workpiece into a process chamber;
forming a vacuum in said process chamber;
forming a plasma of a noble gas in said process chamber;
implanting noble gas ions into said workpiece to a first depth;
filling said process chamber with a dopant species;
depositing said dopant species on said workpiece;
removing said workpiece from said process chamber and breaking said vacuum; and
annealing said workpiece wherein said dopant species diffuses to said first depth of said workpiece.

14. The doping method of claim 13, further comprising moving said workpiece to a load lock under said vacuum prior to said filling.

15. The doping method of claim 13, wherein said implanting amorphizes a crystal lattice of said workpiece.

16. The doping method of claim 13, wherein said workpiece has an oxide coating and further comprising removing said oxide coating from said workpiece prior to said implanting.

17. The doping method of claim 16, wherein said removing comprises sputtering with argon.

18. The doping method of claim 13, wherein said dopant species is selected from the group consisting of boron, phosphorus, arsenic, germanium, and carbon.

19. The doping method of claim 13, wherein said annealing comprising a millisecond anneal.

20. The doping method of claim 13, wherein said forming said vacuum occurs prior to said placing said workpiece.
